(19) United States
(12) Patent Application Publication
(10) Pub. No.: US 2012/0125258 A1
(43) Pub. Date: May 24, 2012

(54) Extended Reactor Assembly with Multiple Sections for Performing Atomic Layer Deposition on Large Substrate

(75) Inventor: Sang In LEE, Sunnyvale, CA (US)

(73) Assignee: SYNOS TECHNOLOGY, INC., Sunnyvale, CA (US)

(21) Appl. No.: 13/295,012

(22) Filed: Nov. 11, 2011

Related U.S. Application Data
(60) Provisional application No. 61/416,931, filed on Nov. 24, 2010.

(51) Int. Cl. C23C 16/50

(52) U.S. Cl. 118/719

(57) ABSTRACT

An elongated reactor assembly in a deposition device for performing atomic layer deposition (ALD) on a large substrate. The elongated reactor assembly includes one or more injectors and/or radical reactors. Each injector or radical reactor injects a gas or radicals onto the substrate as the substrate passes the injector or radical reactor as part of the ALD process. Each injector or radical reactor includes a plurality of sections where at least two sections have different cross sectional configurations. By providing different sections in the injector or radical reactor, the injector or radical reactor may inject the gas or the radicals more uniformly over the substrate. Each injector or radical reactor may include more than one outlet for discharging excess gas or radicals outside the deposition device.

### CROSS-REFERENCE TO RELATED APPLICATION

This application claims priority under 35 U.S.C. §119(e) to co-pending U.S. Provisional Patent Application No. 61/416,931, filed on Nov. 24, 2010, which is incorporated by reference herein in its entirety.

### BACKGROUND

1. Field of Art

The present invention relates to a depositing apparatus for depositing one or more layers of materials on a substrate using atomic layer deposition (ALD).

2. Description of the Related Art

An atomic layer deposition (ALD) is a thin film deposition technique for depositing one or more layers of material on a substrate. ALD uses two types of chemical, one is a source precursor and the other is a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor. ALD can be a slow process that can take an extended amount of time or many repetitions before a layer of desired thickness can be obtained. Hence, to expedite the process, a vapor deposition reactor with a unit module (so-called a linear injector), as described in U.S. Patent Application Publication No. 2009/0165715 or other similar devices may be used to expedite ALD process. The unit module includes an injection unit and an exhaust unit for a source material (a source module), and an injection unit and an exhaust unit for a reactant (a reactant module).

A conventional ALD vapor deposition chamber has one or more sets of reactors for depositing ALD layers on substrates. As the substrate passes below the reactors, the substrate is exposed to the source precursor, a purge gas and the reactant precursor. The source precursor molecules deposited on the substrate reacts with reactant precursor molecules or the source precursor molecules are replaced with the reactant precursor molecules to deposit a layer of material on the substrate. After exposing the substrate to the source precursor or the reactant precursor, the substrate may be exposed to the purge gas to remove excess source precursor molecules or reactant precursor molecules from the substrate.

### SUMMARY

Embodiments relate to a radical reactor in a reactor assembly that includes a body placed adjacent to a susceptor on which the substrate is mounted. The body is formed with a first plasma chamber in a first reactor section extending for a first distance along the length of the radical reactor and a second plasma chamber in a second reactor section extending for a second distance along the length of the radical reactor. A first inner electrode extends within the first plasma chamber. The first inner electrode generates the radicals of a first gas within the first plasma chamber by applying a voltage difference across the first inner electrode and a first outer electrode. A second inner electrode extends within the second plasma chamber. The second inner electrode generates the radicals of the first gas within the second plasma chamber by applying the voltage difference across the second inner electrode and a second outer electrode.

In one embodiment, the body is further formed with an injection chamber, a constriction zone and at least one outlet. The injection chamber is connected to the first plasma chamber and the second plasma chamber to receive the radicals. The radicals are injected onto the substrate from the injection chamber. The constriction zone has a height lower than the height of the injection chamber. At least one outlet is connected to the construction zone. The at least one outlet discharges the radicals from the reactor assembly.

In one embodiment, the first plasma chamber is formed at one side of the injection chamber and the second plasma chamber is formed at the other side of the injection chamber.

In one embodiment, the body is further formed with a first reactor channel in the first reactor section and a second reactor channel in the second reactor section. The first reactor channel is connected to a gas source via a first conduit, and the second reactor channel is connected to the gas source via a second conduit separate from the first conduit.

In one embodiment, the body is further formed with at least two outlets for discharging the radicals from the reactor assembly. The inner surfaces of the at least two outlets join between the outlets.

In one embodiment, the reactor assembly further includes an injector formed with a first injector channel, a second injector channel, a chamber and a constriction zone. The first injector channel is placed in a first injector section of the injector for receiving a second gas via a first conduit. The second injector channel is placed in a second injector section of the injector receiving the second gas via a second conduit. A chamber is connected to the first injector channel and the second injector channel for receiving the gas and injecting the gas onto the substrate, at least one outlet for discharging the gas from the reactor assembly, and a constriction zone connecting the chamber to the at least one outlet. The constriction zone has a height lower than a height of the injection chamber.

In one embodiment, the first injector channel is formed at one side of the injector chamber and the second injector channel is formed at the opposite sided of the chamber.

In one embodiment, the effective length of the reactor assembly is greater than the width of the substrate.

In one embodiment, the first inner electrode includes a core and an outer layer. The core is made of a first material having a higher conductivity compared to a second material of the outer layer.

In one embodiment, the first material comprises copper, silver or alloy thereof; and the second material comprises stainless steel, austenitic nickel-chromium-based superalloy or nickel steel alloy.

Embodiments also relate to a deposition apparatus for depositing one or more layers of material on a substrate using atomic layer deposition (ALD). The deposition apparatus includes a susceptor, a radical reactor and an actuator. The susceptor is mounted with a substrate. The radical reactor includes a body placed adjacent to the susceptor. The body is formed with a first plasma chamber in a first reactor section of the radical reactor extending lengthwise for a first distance and a second plasma chamber in a second reactor section extending lengthwise for a second distance. A first inner electrode extends within the first plasma chamber. The first inner electrode generates the radicals of a first gas within the first plasma chamber by applying a voltage difference across the first inner electrode and a first outer electrode. A second inner electrode extends within the second plasma chamber. The second inner electrode generates the radicals of the first gas within the second plasma chamber by applying the voltage difference across the second inner electrode and a second outer electrode. The actuator causes relative movement between the susceptor and the radical reactor.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of a rotating deposition device, according to one embodiment.

FIG. 4 is a perspective view of a reactor assembly according to one embodiment.

FIG. 5 is a top view of the reactor assembly according to one embodiment.

FIG. 6 is a cross sectional diagram of the reactor assembly taken along line A-A′ or line B-B′ of FIG. 4, according to one embodiment.

FIG. 7 is a cross sectional diagram of the reactor assembly taken along line C-C′ of FIG. 5, according to one embodiment.

FIG. 8 is a cross sectional diagram of the reactor assembly taken along line D-D′ of FIG. 5, according to one embodiment.

FIG. 9 is a cross sectional diagram of the reactor assembly taken along line E-E′ of FIG. 5, according to one embodiment.

FIG. 10 is a top view of a reactor assembly according to another embodiment.

FIG. 11 is a diagram illustrating an inner electrode according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to an elongated reactor assembly in a deposition device for performing atomic layer deposition (ALD) on a wide substrate. The elongated reactor assembly includes one or more injectors and/or radical reactors. As part of the ALD process, each injector or radical reactor injects a gas or radicals onto the substrate as the substrate passes the injector or radical reactor. Each injector or radical reactor includes a plurality of sections where at least two sections have different cross sectional configurations. Different sections receive the gas via different conduits (e.g., pipes). By providing different sections in the injector or radical reactor, the injector or radical reactor may inject the gas or the radicals more uniformly over the substrate. Each injector or radical reactor may include more than one outlet for discharging excess gas or radicals outside the deposition device.

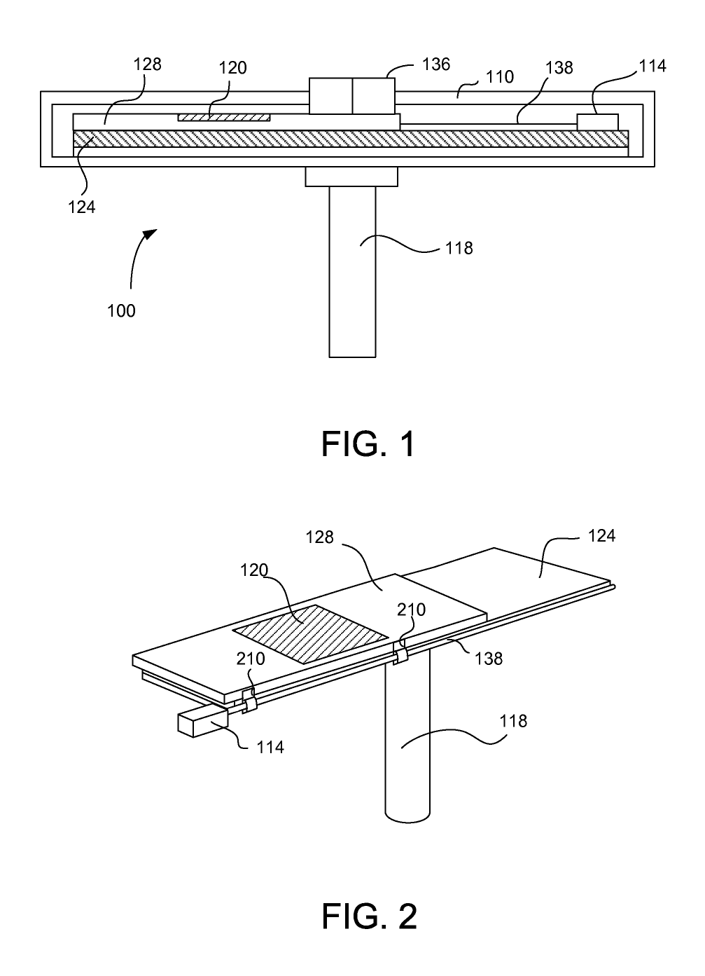

Figure (FIG. 1 is a cross sectional diagram of a linear deposition device 100 according to one embodiment. FIG. 2 is a perspective view of the linear position device 100 (without chamber walls 110 to facilitate explanation) of FIG. 1. The linear deposition device 100 may include, among other components, a support pillar 118, a process chamber 110 and a reactor assembly 136. The reactor assembly 136 may include one or more of injectors and radical reactors. Each of the injector modules injects source precursors, reactant precursors, purge gases or a combination of these materials onto the substrate 120. The radical reactors inject radicals of one or more gases onto the substrate 120. The radicals may function as source precursors, reactant precursors or material for treating the surface of the substrate 120.

The process chamber enclosed by the walls 110 may be maintained in a vacuum state to prevent contaminants from affecting the deposition process. The process chamber contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion at the bottom, top or side of the susceptor 128) may be used. Moreover, instead of moving the susceptor 128, the susceptor 128 may remain stationary and the reactor assembly 136 may be moved.

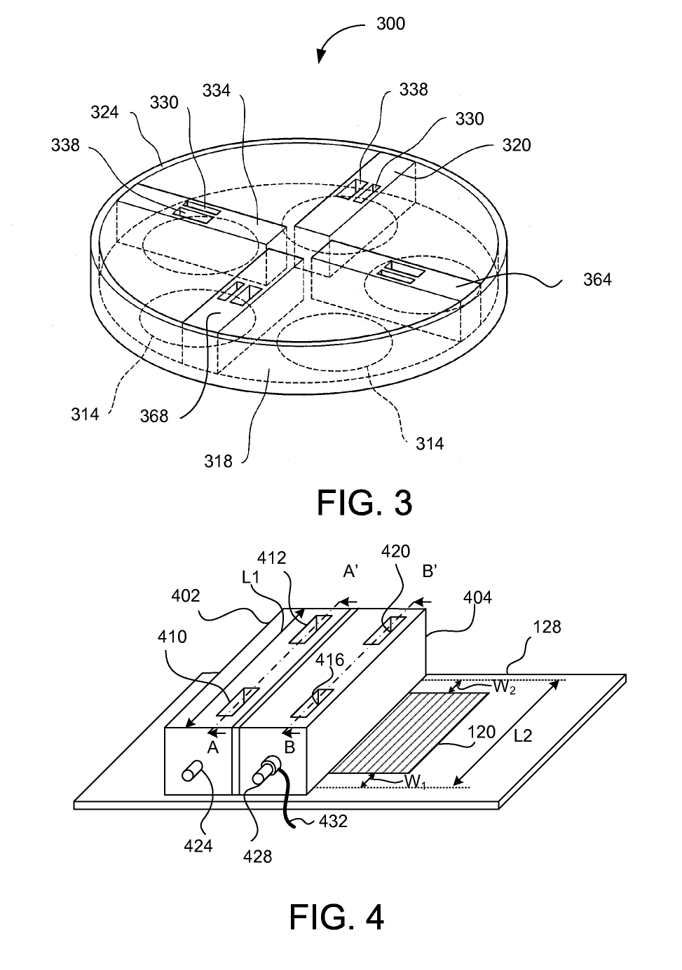

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320, 334, 364, 368 (collectively referred to as the “reactor assembly” herein), a susceptor 318, and a container 324 enclosing these components. The susceptor 318 secures the substrates 314 in place. The reactor assembly is placed above the substrates 314 and the susceptor 318. Either the susceptor 318 or the reactor assembly rotates to subject the substrates 314 to different processes.

One or more of the reactors 320, 334, 364, 368 are connected to gas pipes via inlet 330 to receive source precursor, reactor precursor, purge gas and/or other materials. The materials provided by the gas pipes may be (i) injected onto the substrate 314 directly by the reactors 320, 334, 364, 368, (ii) after mixing in a chamber inside the reactors 320, 334, 364, 368, or (iii) after conversion into radicals by plasma generated within the reactors 320, 334, 364, 368. After the materials are injected onto the substrate 314, the redundant materials may be exhausted through outlets 330.

Embodiments of reactor assembly described herein can be used in deposition devices such as the linear deposition device 100, the rotating deposition device 300 or other types of deposition devices. FIG. 4 is an example of a reactor assembly 136 including an injector 402 and a radical reactor 404 placed in tandem. Both the injector 402 and the radical reactor 404 are elongated to cover the width of the substrate 120. The susceptor 128 mounted with the substrate 120 reciprocates in two directions (i.e., right and left directions in FIG. 4) to expose the substrate 120 to gases and/or radicals injected by the injector 402 and the radical reactor 404. Although only one injector 402 and one radical reactor 404 are illustrated in FIG. 4, many more injectors and/or radical reactors may be provided in the linear deposition device 100. It is also possible to provide only the radical reactor 402 or the injector 404 in the linear deposition device 100.

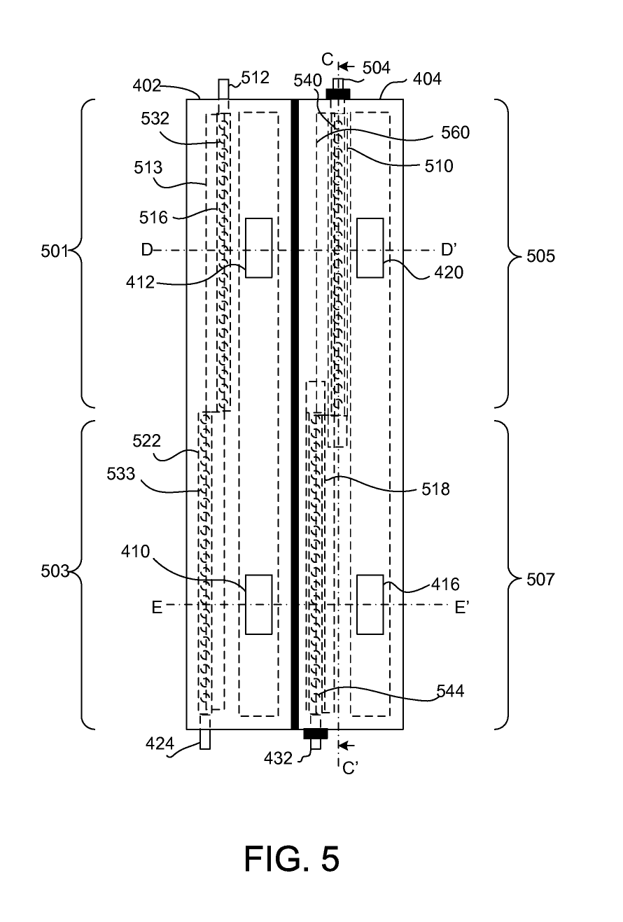

The injector 402 receives gas through pipes (e.g., pipe 424, and pipe 512 illustrated in FIG. 5) and injects the gas onto the substrate 120 as the susceptor 128 moves below the injector 424. The injected gas may be a source gas, a reactant gas, purge gas or a combination thereof. After being injected onto the substrate 120, excess gas in the injector 402 is discharged via outlets 410, 412. The outlets 410, 412 are connected to pipes (not shown) to discharge the excess gas outside the linear deposition device 100. The injector 402 includes two sections having different cross sectional configurations and connected to different injection pipes, as described below in detail with reference to FIG. 5. By providing two outlets 410, 412, the excess gas in the injector 402 can be removed more effectively.

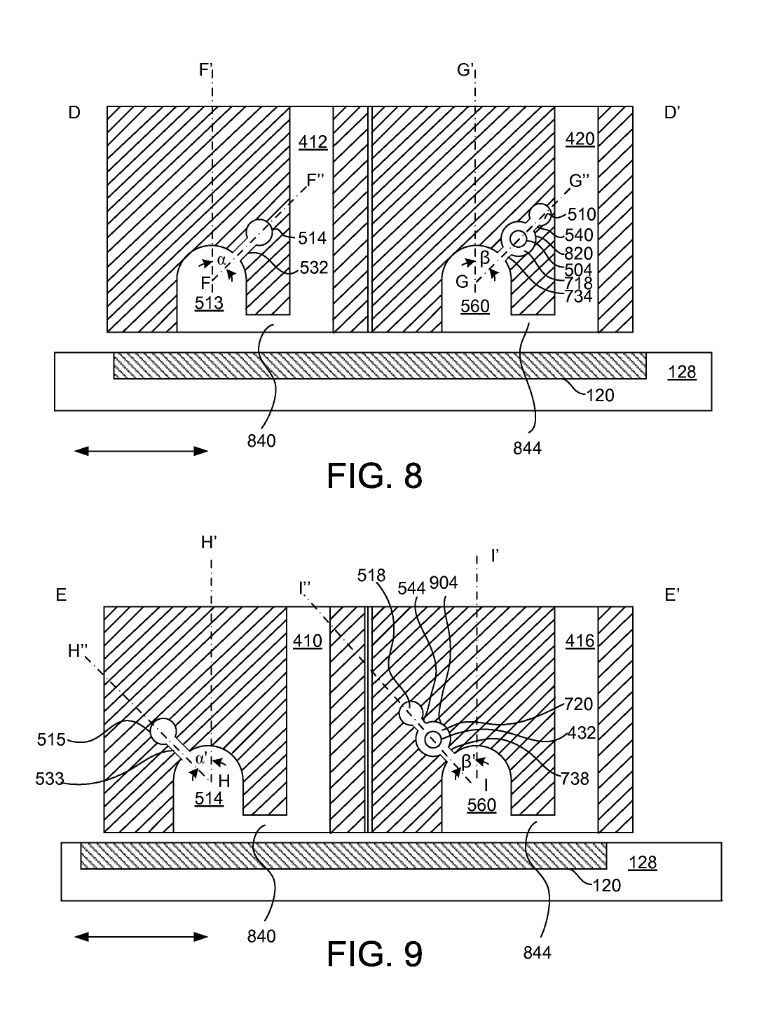

The radical reactor 404 receives gases via pipes (not shown) and has two sections with different cross sectional configurations and separate inner electrodes. Channels are formed in the body of the radical reactor 404 to convey the received gases to the plasma chambers. Two inner electrodes extend approximately halfway across the radical reactor 404 and are connected to a voltage source (not shown) or ground (not shown) via wires 432. The inner electrodes are placed inside plasma chambers, as described below in detail with reference to FIGS. 8 and 9. The outer electrodes in the radical reactor 404 are connected to ground or a voltage source. In one embodiment, the conductive body of the radical reactor 404 functions as the outer electrodes. Outlets 416, 420 are formed in the body of the radical reactor 404 to discharge excess radicals and/or gases (reverted to an inactive state from the radicals during, before or after being injected onto the substrate 120 out of the deposition device 100). The outlets 416, 420 are connected to pipes (not shown) to discharge the excess radicals and/or gases outside the linear deposition device 100. By providing two outlets 416, 420, the excess gas in the radical reactor 404 can be removed more effectively despite the long length of the radical reactor 404.

As illustrated in FIG. 4, the effective length L2 of the reactor assembly is longer than the width of the substrate 120 by W₁+W₂. The effective length L2 refers to the length across the reactor assembly where the ALD processing is performed on the substrate 120 with a predefined level of quality. The predetermined level of quality may be represented as characteristics or properties of the layer deposited on the substrate. Because the deposition is not performed in a uniform and consistent manner at the side edges of the reactor assembly, the effective length tends to be shorter than the actual length L1 of the reactor assembly. In one embodiment, the substrate has a width of 500 mm or more.

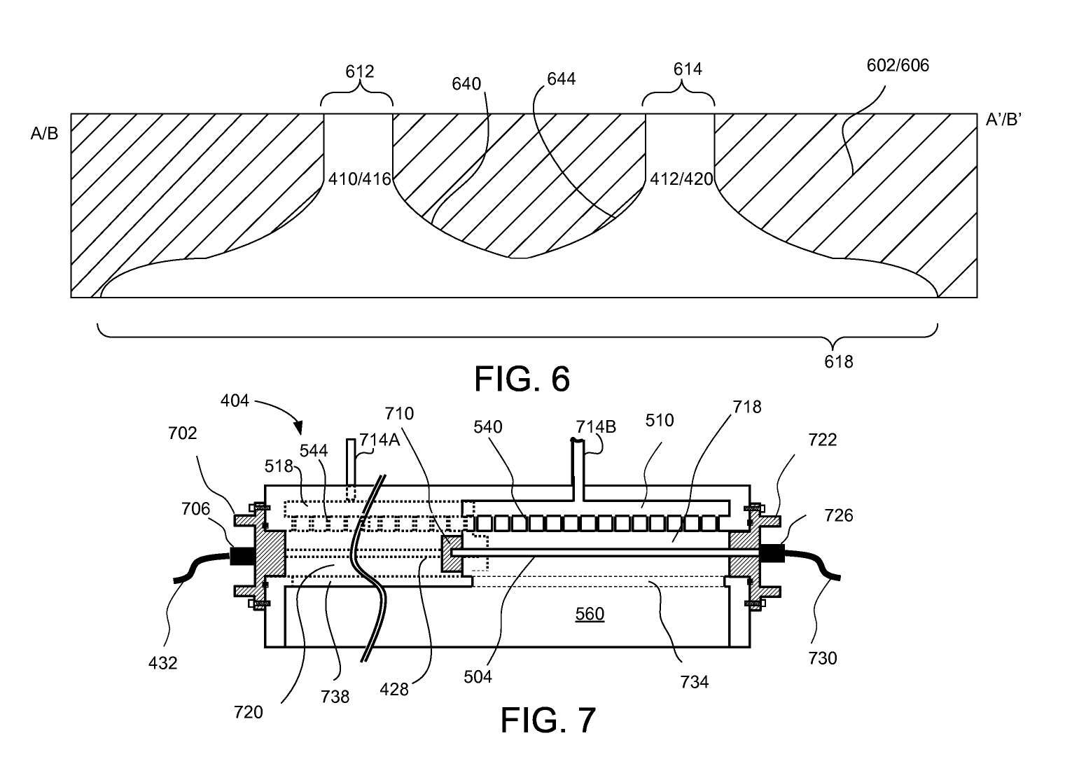

FIG. 5 is a top view of the reactor assembly (i.e., the injector 402 and the radical reactor 404) according to one embodiment. The injector 402 has two injector sections 501, 503 with different cross sectional configurations. The body 602 (see FIG. 6) of the injector 402 in the injector section 501 is formed with a channel 516 connected to a pipe 512 for receiving a gas from a gas source. The channel 516 is connected to an injector chamber 513 via holes 532 to receive the gas. Similarly, the section 503 of the injector 402 is formed with a channel 522 connected to a pipe 424 for receiving the gas (the same gas supplied via the pipe 512) from the gas source. The channel 522 is connected to the injector chamber 513 via the holes 533. The connective relationship of the channels 516, 522, holes 532, 533 and the injector chamber 513 is described below in detail with reference to FIGS. 8 and 9. By providing the gas into the injector chamber 513 via multiple pipes and channels, the gas can be distributed evenly in the injector chamber 513 throughout the injector chamber 513.

Similarly, the radical reactor 404 has two reactor sections 505, 507 with different cross sectional configurations. The body 606 (see FIG. 6) of the radical reactor 404 is formed with channels 510, 518 that are connected to pipes 714A, 714B (see FIG. 7) for receiving a gas from a gas source. The channel 510 is connected to a plasma chamber (indicated by reference numeral 718 in FIGS. 7 and 8) also formed in the reactor section 505 of the body 606. An inner electrode 504 extends within the plasma chamber 718 approximately halfway across the length of the radical reactor 404 to generate plasma within the plasma chamber 718 in conjunction with an outer electrode (indicated by reference numeral 820 in FIG. 8) when a voltage difference is applied across the electrodes 504, 820. The channel 518 is connected to a plasma chamber (indicated by reference numeral 720 in FIGS. 7 and 9) formed in the section 507 of the body 606. The inner electrode 432 extends within the plasma chamber 720 approximately halfway across the length of the radical reactor 404 to generate plasma within the plasma chamber 720 in conjunction with an outer electrode (indicated by reference numeral 904 in FIG. 9) when a voltage difference is applied across the electrodes 432, 904. By providing two separate plasma chambers 828, 720 in the body 606 of the radical reactor 404, radicals of the gas can be generated more evenly across the length of the radical reactor 404.

FIG. 6 is a cross sectional diagram of the injector 402 or radical reactor 404 taken along line A-A′ or B-B′ of FIG. 4, according to one embodiment. The injector 402 has a body 602 with outlets 410, 412 formed thereon. The outlets 410, 412 are cavities adjoining at a lower center section of the body 602. The bottom part 618 of the outlets 410, 412 extends substantially across the length of the injector 402 while the upper parts 612, 614 of the outlets 410, 412 are smaller for connection to discharge pipes. The outlets 410 and 412 have contoured inner surfaces 640, 644 that join smoothly by forming a curve at the lower middle portion of the radical reactor 404.

As for the radical reactor 404, the radical reactor 404 has a body 606 with outlets 416, 420 formed thereon. The outlets 416, 420 are cavities adjoining at a center section of the body 606. The bottom part 618 of the outlets 416, 420 extends substantially across the length of the radical reactor 404 while the upper parts 612, 614 of the outlets 416, 420 are smaller for connection to discharge pipes. The outlets 416 and 420 have contoured inner surfaces 640, 644 that join smoothly around the middle of the radical reactor 404.

As the length of the injector 402 or radical reactor 404 increases, vacuum conductivity within the injector 402 or the radical reactor 404 may be decreased. The decrease in the vacuum conductivity results in decreased efficiency in discharging the gases or radicals remaining in the injector 402 or radical reactor 404. By providing multiple outlets, the vacuum conductivity can be enhanced. This contributes to more efficient discharge of the gases or radicals from the injector 402 or the radical reactor 404.

Although only two outlets are formed in the injector 402 and the radical reactor 404, more than two outlets can be formed in the injector 402 and the radical reactor 404 depending on the length of the injector 402 or the radical reactor 404.

FIG. 7 is a cross sectional diagram of the radical reactor 404 in the reactor assembly taken along line C-C′ of FIG. 5, according to one embodiment. The radical reactor 404 has two inner electrodes 428, 504, each extending approximately halfway across the length of the radical reactor 404. The inner electrode 428 is placed in the plasma chamber 720, and is secured by an end cap 702 and a holder (not shown). Similarly, the inner electrode 504 is placed in the plasma chamber 718, and is also secured to an end cap 722 and a holder 710. The end caps 702, 722 and the holders (e.g., holder 710) are made of insulating material such as ceramic to prevent shorting between the inner electrodes 428, 504 and the body 606 of the radical reactor 404. The holders (e.g., holder 710) are structured to hold the inner electrodes 428, 504 while allowing thermal expansion of the inner electrodes 428, 504. The end caps 702, 722 are secured to the body 606 of the radical reactor 404 by screws. The wires 432, 730 are connects the ends 706, 726 of the inner electrodes 432, 504 to a voltage source.

During the operation of the radical reactor 404, the gas is injected into channels 510, 518 via pipes 714A, 714B. The gas flows into the plasma chamber 718, 720 via holes 540, 544. Plasma is generated in the plasma chamber 718, 720, resulting in radicals of the gas. The radicals are then injected via the slits 734, 738 into the injection chamber 560 formed on the bottom part of the radical reactor 404.

FIG. 8 is a cross sectional diagram of the reactor assembly taken along line D-D′ of FIG. 5 at injector sections 501, 505, according to one embodiment. In the embodiment of FIG. 8, the channel 514 and the holes 532 are aligned along plane F-F″. Plane F-F″ is slanted to the right side at an angle of a with respect to a vertical plane F-F′. After the gas is injected into an injection chamber 513 via the channel 514 and the holes 532, the gas travels down towards the substrate 120 and comes into contact with the substrate 120. Then the gas flows through a constriction zone 840, during which excess materials (e.g., physisorbed source or reactant precursors) are removed from the substrate 120. The excess gas is discharged outside the radical reactor via the outlet 412.

Similarly, the channel 510, the holes 540, the plasma chamber 718 and the inner electrode 504 are aligned along plane G-G″. Plane G-G″ is slanted at an angle of β with respect to the vertical plane G-G′. The angle α and the angle β may have an identical or different amplitude.

The gas injected into the plasma chamber 718 via the channel 510 and the holes 540 are converted into radicals by applying a voltage difference across the inner electrode 504 and an outer electrode 820. The generated radicals travel via the slit 734 into the injection chamber 560. Within the injection chamber 560, the radicals move towards the substrate 120, and come into contact with the substrate 120. The radicals may function as a source precursor, a reactant precursor or as surface treating material on the substrate 120. The remaining radicals (and/or gases reverted to an inactive state) pass a constriction zone 844 and are discharged via the outlet 420.

FIG. 9 is a cross sectional diagram of the reactor assembly taken along line E-E′ of FIG. 5 at sections 503, 507, according to one embodiment. In the embodiment of FIG. 9, the channel 515 and the holes 533 are aligned along plane H-H″. Plane H-H″ is slanted to the left side at an angle of α′ with respect to a vertical plane H-H′. After the gas is injected into the injection chamber 514 via the channel 515 and the holes 533, the gas travels down towards the substrate 120, and comes into contact with the substrate 120. Then the gas flows through a constriction zone 840 and are removed from the reactor assembly via the outlet 410.

The channel 518, the holes 544, the plasma chamber 720 and the inner electrode 432 are aligned along plane I-I″. Plane I-I″ is slanted at an angle of β′ with respect to the vertical plane I-I′. Within the injection chamber 560, the radicals move towards the substrate 120, and come into contact with the substrate 120. The radicals may function as a source precursor, a reactant precursor or as surface treating material on the substrate 120. The remaining radicals (and/or gases reverted to an inactive state) pass a constriction zone 844 and are discharged via the outlet 420. The angle α′ and the angle β′ may be of identical or different amplitude.

Embodiments described above with reference to FIGS. 4 through 9 are merely illustrative. Various modifications or alterations can be made to the embodiments. For example, the holes 540, 544, 836, 908 need not be aligned in the same plane with the channels 510, 518, 514. 515. Also, perforations other than holes or slits may be used to convey gases or radicals to the substrate 120. The injection chambers 514, 560 may have various other shapes than what are illustrated in FIGS. 8 and 9. Further, the outlets may be formed on both sides

(the left and the right sides) of the injector or radical reactor instead of being provided only on one side (e.g., the right side as illustrated in FIGS. 8 and 9).

In one embodiment, the reactor assembly deposits a layer of Al₂O₃ on the substrate 120 by having the injector 402 inject Trimethylaluminium (TMA) onto the substrate 120 as a source precursor and the radical reactor 404 inject radicals of N₂O or O₂ as a reactant precursor onto the substrate. Various other materials may be used as source precursors and reactant precursors to deposit other materials on the substrate.

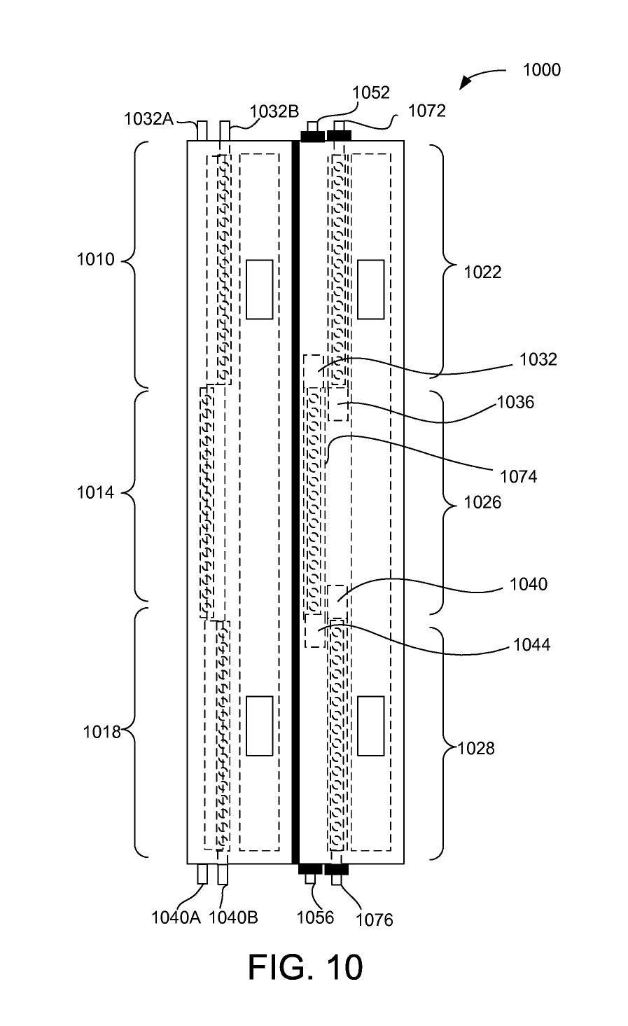

FIG. 10 is a top view of a reactor assembly 1000 according to another embodiment. The reactor assembly 1000 is similar to the reactor assembly described above with reference to FIGS. 4 through 9 except that the injector and the radical assembly are divided into three separate sections. The injector of FIG. 10 includes injector sections 1010, 1014, 1018 of an approximately equal length; and the radical reactor includes reactor sections 1022, 1026, 1028 of an approximately equal length. In this embodiment, pipes 1032A and 1040A are connected to a channel in section 1014 of the injector. Pipe 1032B is connected to a channel in section 1010, and pipe 1040B is connected to a channel in section 1018 of the injector.

The radical reactor of FIG. 10 is also similar to the radical reactor of FIGS. 4 through 9 but has three inner electrodes 1072, 1074, 1076, each provided in one of the sections 1022, 1026, 1028. The three inner electrodes 1072, 1074, 1076 are secured by holders 1032, 1036, 1040, 1044 to insulate the inner electrodes 1072, 1074, 1076 from the body of the radical reactor. The inner electrode 1074 is connected to terminals 1052, 1056 via wires or other conducting materials.

Depending on the size and the use of the reactor assembly, its injectors or radical reactors may be divided into more than three sections. The sections need not be of an equal length, and the sections of the injectors and the radical reactors may have different lengths. In one embodiment, the total lengths of the injectors and the radical reactors are different. Further, the injectors and the radical reactors need not be placed and tandem, and can be placed remotely from each other.

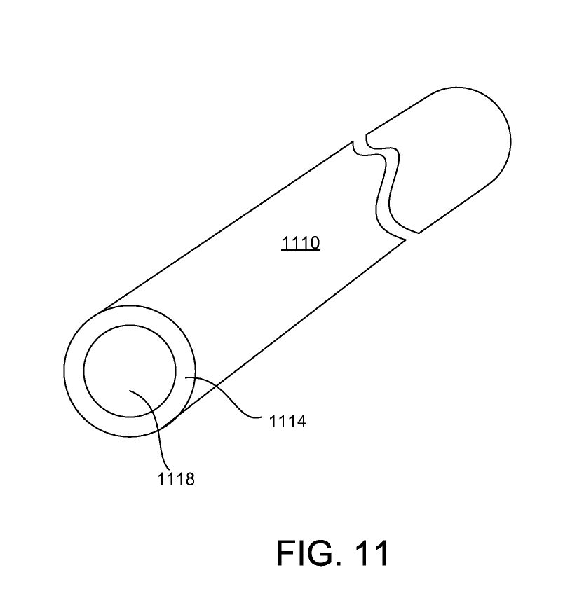

FIG. 11 is a diagram illustrating an inner electrode 1110 according to one embodiment. As the length of the electrode 1110 increases, the resistance of the electrode 1110 may also increase. The electrode 1110 may have an outer layer 1114 and a core 1118. In one embodiment, the outer layer 1114 is made of stainless steel, austenitic nickel-chromium-based superalloy (e.g., INCONEL) or nickel steel alloy (e.g., INVAR), and the core 1118 is made of copper, silver or their alloy. For example, copper or silver may be injected into a pipe made of stainless steel or an alloy to form the core 1118. Alternatively, a rod made of copper, silver or their alloy may for the core 1118, which is plated with materials such as nickel to form the outer layer 1114. By providing a core with higher conductivity, the overall conductivity of the electrode 1110 is increased, contributing to more uniform and consistent generation of radicals along the length of the electrode 1110 in a plasma channel. In one embodiment, the inner electrode 1110 has a diameter of 3 to 10 mm.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A reactor assembly in a depositing device for performing atomic layer deposition (ALD), comprising:
a radical reactor comprising:
a body placed adjacent to a susceptor on which the substrate is mounted, the body formed with a first plasma chamber in a first reactor section of the radical reactor extending lengthwise for a first distance and a second plasma chamber in a second reactor section extending lengthwise for a second distance;
a first inner electrode extending within the first plasma chamber, the first inner electrode configured to generate the radicals of a first gas within the first plasma chamber by applying a voltage difference across the first inner electrode and a first outer electrode; and
a second inner electrode extending within the second plasma chamber, the second inner electrode configured to generate the radicals of the first gas within the second plasma chamber by applying the voltage difference across the second inner electrode and a second outer electrode.

2. The reactor assembly of claim 1, wherein the body is further formed with:
an injection chamber connected to the first plasma chamber and the second plasma chamber to receive the radicals, wherein the radicals are injected onto the substrate from the injection chamber;
a constriction zone with a height lower than a height of the injection chamber; and
at least one outlet connected to the construction zone, the at least one outlet configured to discharge the radicals from the reactor assembly.

3. The reactor assembly of claim 1, wherein the first plasma chamber is formed at one side of the injection chamber and the second plasma chamber is formed at the other side of the injection chamber.

4. The reactor assembly of claim 1, wherein the body is further formed with a first reactor channel in the first reactor section and a second reactor channel in the second reactor section, the first reactor channel connected to a gas source via a first conduit, and the second reactor channel connected to the gas source via a second conduit separate from the first conduit.

5. The reactor assembly of claim 1, wherein the body is further formed with at least two outlets for discharging the radicals from the reactor assembly, two of the at least two outlets having inner surfaces that join at a location between the two outlets.

6. The reactor assembly of claim 1, further comprising an injector formed with:
a first injector channel in a first injector section of the injector for receiving a second gas via a first conduit;
a second injector channel in a second injector section of the injector receiving the second gas via a second conduit;
a chamber connected to the first injector channel and the second injector channel for receiving the gas and injecting the gas onto the substrate, at least one outlet for discharging the gas from the reactor assembly; and
a constriction zone connecting the chamber to the at least one outlet, the constriction zone having a height lower than a height of the injection chamber.

7. The reactor assembly of claim 6, wherein the first injector channel is formed at one side of the chamber and the second injector channel is formed at the other sided of the chamber.

8. The reactor assembly of claim 1, wherein an effective length of the reactor assembly is greater than a width of the substrate.

9. The reactor assembly of claim 1, wherein the first inner electrode includes a core and an outer layer, the core made of a first material having a higher conductivity compared to a second material of the outer layer.

10. The reactor assembly of claim 9, wherein the first material comprises copper, silver or alloy thereof; and the second material comprises stainless steel, austenitic nickel-chromium-based superalloy or nickel steel alloy.

11. A deposition apparatus for depositing one or more layers of material on a substrate using atomic layer deposition (ALD), comprising:
a susceptor configured to mount a substrate;
a radical reactor comprising:
a body placed adjacent to the susceptor, the body formed with a first plasma chamber in a first reactor section of the radical reactor extending lengthwise for a first distance and a second plasma chamber in a second reactor section extending lengthwise for a second distance;
a first inner electrode extending within the first plasma chamber, the first inner electrode configured to generate the radicals of a first gas within the first plasma chamber by applying a voltage difference across the first inner electrode and a first outer electrode; and
a second inner electrode extending within the second plasma chamber, the second inner electrode configured to generate the radicals of the first gas within the second plasma chamber by applying the voltage difference across the second inner electrode and a second outer electrode; and
an actuator configured to cause relative movement between the susceptor and the radical reactor.

12. The deposition apparatus of claim 11, wherein the body is further formed with:
an injection chamber connected to the first plasma chamber and the second plasma chamber to receive the radicals, wherein the radicals are injected onto the substrate from the injection chamber;
a constriction zone with height lower than the injection chamber; and
at least one outlet connected to the construction zone, the at least one outlet configured to discharge the radicals from the reactor assembly.

13. The deposition apparatus of the claim 11, wherein the first plasma chamber is formed at one side of the injection chamber and the second plasma chamber is formed at the other side of the injection chamber.

14. The deposition apparatus of claim 11, wherein the body is further formed with a first reactor channel in the first reactor section and a second reactor channel in the second reactor section, the first reactor channel connected to a gas source via a first conduit, and the second reactor channel connected to the gas source via a second conduit separate from the first conduit.

15. The deposition apparatus of claim 11, wherein the body is further formed with at least two outlets for discharging the radicals from the reactor assembly with inner surface of the at least two outlets joining between the at least outlets.

16. The deposition apparatus of claim 11, further comprising an injector formed with:
a first injection channel in a first injector section of the injector for receiving a second gas via a first conduit;
a second injection channel in a second injector section of the injector receiving the second gas via a second conduit;
a chamber connected to the first injection channel and the second injection channel for receiving the gas and injecting the gas onto the substrate, at least one outlet for discharging the gas from the reactor assembly; and
a constriction zone connecting the chamber to the at least one outlet, the constriction zone having a height lower than a height of the injection chamber.

17. The deposition apparatus of claim 16, wherein the first injection channel is formed at one side of the chamber and the second injection channel is formed at the opposite sided of the chamber.

18. The deposition apparatus of claim 11, wherein an effective length of the reactor assembly is greater than a width of the substrate.

19. The deposition apparatus of claim 11, wherein the first inner electrode includes a core and an outer layer, the core made of a first material having a higher conductivity compared to a second material of the outer layer.

20. The deposition apparatus of claim 19, wherein the first material comprises copper, silver or alloy thereof; and the second material comprises stainless steel, austenitic nickel-chromium-based superalloy or nickel steel alloy.
